(19) United States
(12) Patent Application Publication
(10) Pub. No.: US 2007/0181892 A1
(43) Pub. Date: Aug. 9, 2007

(54) IMAGE DISPLAY DEVICE

(76) Inventors: Sachiko HIRAHARA, Fukaya-shi (JP); Satoko Oyaizu, Fukaya-shi (JP); Satoshi Ishikawa, Fukaya-shi (JP); Kentaro Shimayama, Fukaya (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/681,239

(22) Filed: Mar. 2, 2007

Related U.S. Application Data
(63) Continuation of application No. PCT/JP05/15926, filed on Aug. 31, 2005.

(30) Foreign Application Priority Data
Sep. 3, 2004 (JP) 2004-257091

(51) Int. Cl. H01L 33/00

(52) U.S. Cl. 257/89

(57) ABSTRACT

A spacer structure is provided between a first substrate formed with a phosphor screen and a second substrate provided with a plurality of electron emission sources. A supporting substrate of the spacer structure has a first surface opposed to the first substrate, a second surface opposed to the second substrate, and a plurality of electron beam apertures opposed to the electron emission sources. A plurality of spacers are set up on the second surface. The supporting substrate has a plurality of height reducing portions which are individually in contact with the spacers and elastically deformable in the height direction of the spacers. Each of the height reducing portions has a recess formed in the first surface so as to face the spacer and a plurality of grooves formed on the second surface and situated around the spacer.

### CROSS-REFERENCE TO RELATED APPLICATIONS

This is a Continuation Application of PCT Application No. PCT/JP2005/015926, filed Aug. 31, 2005, which was published under PCT Article 21(2) in Japanese.

This application is based upon and claims the benefit of priority from prior Japanese Patent Application No. 2004-257091, filed Sep. 3, 2004, the entire contents of which are incorporated herein by reference.

### BACKGROUND OF THE INVENTION

1. Field of the Invention

This invention relates to an image display device provided with substrates located opposite each other and spacers located between the substrates.

2. Description of the Related Art

In recent years, various flat-type image display devices have been noticed as a next generation of lightweight, thin display devices to replace cathode-ray tubes (CRTs). For example, a surface-conduction electron emission device (SED) has been developed as a kind of a field emission device (FED) that functions as a flat-type display device.

This SED comprises a first substrate and a second substrate that are located opposite each other with a predetermined space between them. These substrates have their respective peripheral portions joined together by a rectangular sidewall, thereby forming a vacuum envelope. Three-color phosphor layers and a metal back are formed on the inner surface of the first substrate. Arranged on the inner surface of the second substrate are a large number of electron emitting elements for use as electron sources, which correspond to pixels, individually, and excite the phosphors.

For the SED described above, it is important to maintain a high degree of vacuum in the space between the first substrate and the second substrate, that is, in the vacuum envelope. If the degree of vacuum is low, the life of the electron emitting elements, and hence, the life of the device shorten inevitably. Since a vacuum is maintained between the first substrate and the second substrate, moreover, an atmospheric pressure acts on the first substrate and the second substrate. In order to support the atmospheric load that acts on these substrates and maintain the gap between the substrates, therefore, a large number of plate-like or columnar spacers are located between the two substrates.

In order to locate the spacers to cover the first substrate and the second substrate entirely, spacers in the form of very thin plates or very slender columns should be used lest they touch the phosphors on the first substrate or the electron emitting elements on the second substrate. More spacers are needed in order to make the first substrate and the second substrate thinner. Disclosed in Jpn. Pat. Appln. KOKAI Publication No. 2001-272927, for example, is a device in which a large number of columnar spacers are set up on a supporting substrate to form a spacer structure, and this spacer structure is located between the first and second substrates.

In the spacer structure with a large number of spacers, as described above, it is difficult to form all the spacers with the same height, and the spacers may possibly be subject to dispersion in height. If the spacers are subject to dispersion in height, it is hard to stably support an atmospheric load that acts on the first substrate and the second substrate by means of the spacers, so that the atmospheric pressure resistance of the envelope lowers. A heavier load acts on taller spacers, so that those spacers may possibly be damaged. In this case, the strength of the spacer structure itself lowers. If there are shorter spacers, in contrast with this, gaps are formed between the distal ends of the spacers and the substrate, possibly causing generation of electric discharge.

### BRIEF SUMMARY OF THE INVENTION

This invention has been made in consideration of these circumstances, and its object is to provide an image display device with improved atmospheric pressure resistance in which generation of electric discharge is suppressed.

According to an aspect of the invention, there is provided an image display device comprising: an envelope having a first substrate formed with a phosphor screen and a second substrate which is located opposite the first substrate across a gap and on which a plurality of electron emission sources for electron emission toward the phosphor screen are located; a supporting substrate located between the first and second substrates and having a first surface opposed to the first substrate, a second surface opposed to the second substrate, and a plurality of electron beam apertures opposed to the electron emission sources; and a plurality of columnar spacers which are set up between the second surface of the supporting substrate and the second substrate and support an atmospheric pressure acting on the first and second substrates, the supporting substrate having a plurality of height reducing portions being individually in contact with the spacers and elastically deformable in the height direction of the spacers, each of the height reducing portions having a recess formed in the first surface so as to face the spacer and a plurality of grooves formed on the second surface and situated around the spacer.

According to another aspect of the invention, there is provided an image display device comprising: an envelope having a first substrate formed with a phosphor screen and a second substrate which is located opposite the first substrate across a gap and on which a plurality of electron emission sources for electron emission toward the phosphor screen are located; a supporting substrate located between the first and second substrates and having a first surface opposed to the first substrate, a second surface opposed to the second substrate, and a plurality of electron beam apertures opposed to the electron emission sources; and a plurality of columnar spacers which are set up between the second surface of the supporting substrate and the second substrate and support an atmospheric pressure acting on the first and second substrates, the supporting substrate having a plurality of height reducing portions being individually in contact with the spacers and elastically deformable in the height direction of the spacers, each of the height reducing portions having a recess formed in the first surface so as to face the spacer, the electron beam apertures on the opposite sides of each spacer in each of the height reducing portions being larger than the other electron beam apertures.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a perspective view showing an SED according to a first embodiment of this invention;

FIG. 2 is a perspective view of the SED broken away along line II-II of FIG. 1;

FIG. 3 is a first-direction sectional view enlargedly showing the SED;

FIG. 4 is a second-direction sectional view enlargedly showing the SED;

FIG. 5 is a plan view showing the second surface side of a spacer structure of the SED;

FIG. 6 is a plan view showing the first surface side of the spacer structure;

FIG. 7 is a perspective view enlargedly showing a part of the spacer structure;

FIG. 8 is a second-direction sectional view enlargedly showing the SED with a height reducing portion of the spacer structure deformed;

FIG. 9 is a plan view showing a spacer structure of an SED according to a second embodiment of this invention;

FIG. 10 is a plan view showing a spacer structure of an SED according to a third embodiment of this invention; and

FIG. 11 is a plan view showing a spacer structure of an SED according to a fourth embodiment of this invention.

### DETAILED DESCRIPTION OF THE INVENTION

An embodiment in which this invention is applied to an SED as a flat-type image display device will now be described in detail with reference to the drawings.

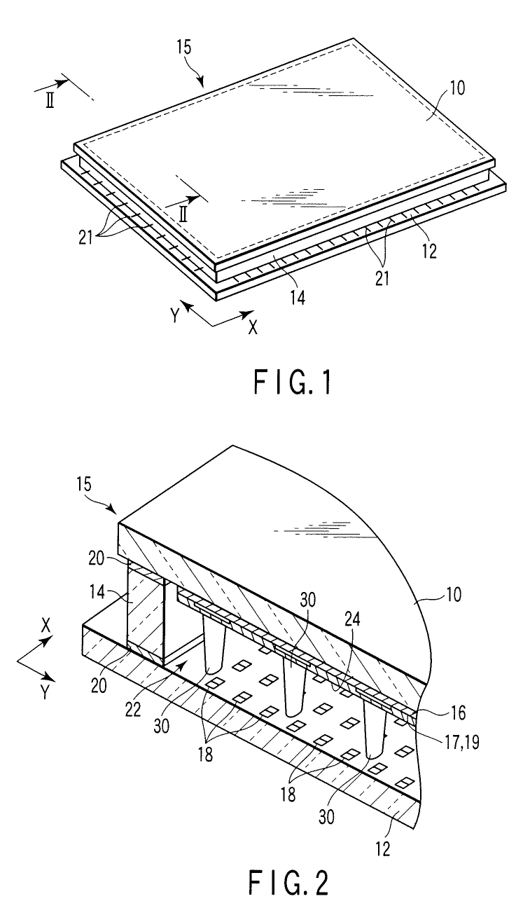

As shown in FIGS. 1 to 4, the SED comprises a first substrate 10 and a second substrate 12, which are formed of a rectangular glass plate each. These substrates are located opposite each other with a gap of about 1.0 to 2.0 mm between them. The first substrate 10 and the second substrate 12 have their respective peripheral edge portions joined together by a rectangular sidewall 14 of glass, thereby forming a flat rectangular vacuum envelope 15 of which the inside is kept vacuum. The sidewall 14 that functions as a joint member is sealed to the peripheral edge portion of the first substrate 10 and the peripheral edge portion of the second substrate 12 with a sealant 20 of, for example, low-melting-point glass or low-melting-point metal, whereby these substrates are joined together.

A phosphor screen 16 that functions as a phosphor screen is formed on the inner surface of the first substrate 10. The phosphor screen 16 is formed by arranging side by side phosphor layers R, G and B, which glow red, blue, and green, individually, and a light shielding layer 11. These phosphor layers are stripe-shaped or dot-shaped. A metal back layer 17 of aluminum or the like and a getter film 19 are successively formed on the phosphor screen 16.

Provided on the inner surface of the second substrate 12 are a large number of surface-conduction electron emitting elements 18 for use as electron sources, which individually emit electron beams and excite the phosphor layers R, G and B of the phosphor screen 16. These electron emitting elements 18 are arrayed in a plurality of columns and a plurality of rows corresponding to pixels. Each electron emitting element 18 is formed of an electron emitting portion (not shown), a pair of element electrodes that apply voltage to the electron emitting portion, etc. Further, a large number of wires 21 that apply potential to the electron emitting elements 18 are provided in a matrix on the inner surface of the second substrate 12, and their respective end portions are led out of the vacuum envelope 15.

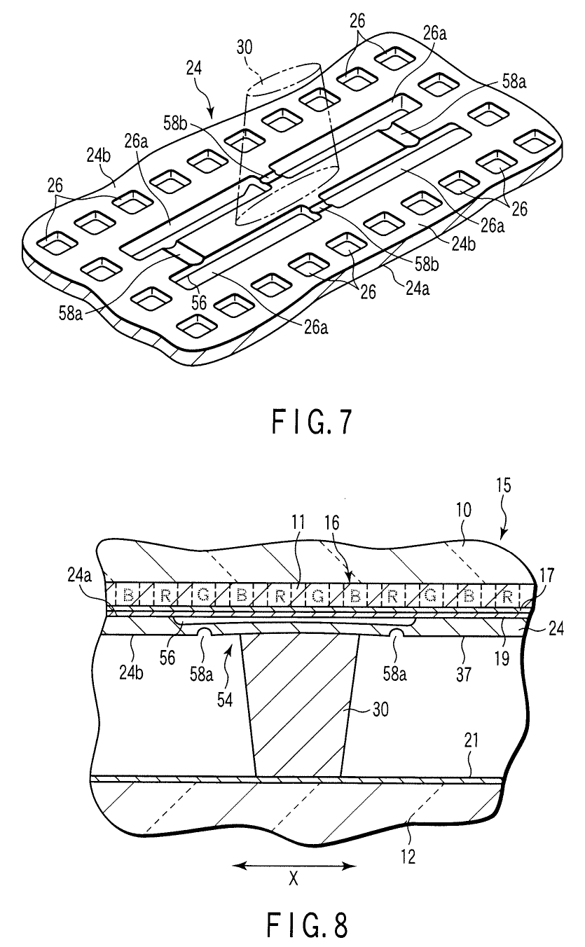

As shown in FIGS. 2 to 7, the SED comprises a spacer structure 22, which is located between the first substrate 10 and the second substrate 12. The spacer structure 22 is provided with a supporting substrate 24, formed of a metal plate, and a large number of columnar spacers 30 set up integrally on the supporting substrate. The supporting substrate 24 is formed having a rectangular shape that corresponds to the phosphor screen 16 in size. It has a first surface 24a opposed to the inner surface of the first substrate 10 and a second surface 24b opposed to the inner surface of the second substrate 12, and is located parallel to these substrates. A large number of electron beam apertures 26 are formed in the supporting substrate 24 by etching or the like. The electron beam apertures 26 are arrayed opposite the electron emitting elements 18, individually, and are permeated by the electron beams emitted from the electron emitting elements. It has a first surface 24a opposed to the inner surface of the first substrate 10 and a second surface 24b opposed to the inner surface of the second substrate 12, and is located parallel to these substrates.

The supporting substrate 24 is formed of a plate of, for example, an iron-nickel-based metal with a thickness of 0.1 to 0.25 mm. A plurality of electron beam apertures 26 are formed in the supporting substrate 24 by etching or the like. As mentioned later, all the electron beam apertures 26 but some are formed having a rectangular shape measuring 0.15 to 0.25 mm×0.15 to 0.25 mm, for example. If the longitudinal direction of the first substrate 10 and the second substrate 12 and the transverse direction perpendicular thereto are a first direction X and a second direction Y, respectively, the electron beam apertures 26 are arrayed at predetermined pitches along the first direction X and at pitches larger than the pitches in the first direction X along the second direction Y. The phosphor layers R, G and B of the phosphor screen 16 formed on the first substrate 10 and the electron emitting elements 18 on the second substrate 12 are arrayed at the same pitches as the electron beam apertures 26 with respect to the first direction X and the second direction Y, and face the electron beam apertures, individually.

The first and second surfaces 24a and 24b of the supporting substrate 24 and the respective inner wall surfaces of the electron beam apertures 26 are covered by an insulating layer 37, which is formed of an insulating material consisting mainly of glass or the like, e.g., Li-based alkaline borosilicic acid glass, and has a thickness of about 40 μm.

The supporting substrate 24 is provided in a manner such that its first surface 24a is in contact with the getter film 19 on the first substrate 10 with the insulating layer 37 between them. The electron beam apertures 26 in the supporting substrate 24 face the phosphor layers R, G and B of the phosphor screen 16 and the electron emitting elements 18 on the second substrate 12, individually. Thus, the electron emitting elements 18 face their corresponding phosphor layers through the electron beam apertures 26, individually.

The large number of spacers 30 are set up integrally on the second surface 24b of the supporting substrate 24. The respective extended ends of the spacers 30 abut on the inner surface of the second substrate 12, that is, on the wires 21 provided on the inner surface of the second substrate 12 in this case. The wires 30 are situated individually between the electron beam apertures 26 that are arranged in the second direction Y. The plurality of spacers 30 are provided side by side at predetermined pitches in the second direction Y and at pitches larger than the aforesaid predetermined pitches in the first direction X.

Each of the spacers 30 is tapered so that its diameter is reduced from the supporting substrate 24 side toward its extended end. For example, each spacer 30 is formed having a height of about 1.8 mm. The cross section of each spacer 30 along a direction parallel to the grid surface is substantially elliptic. Each of the spacers 30 is formed mainly of a spacer forming material that consists mainly of glass as an insulating material.

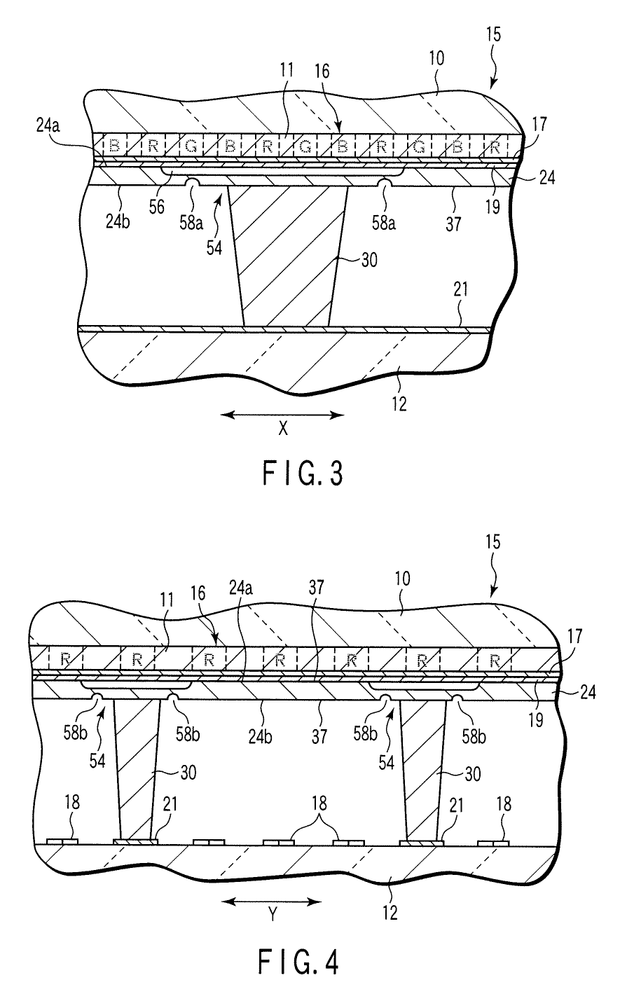

As shown in FIGS. 3 to 7, the supporting substrate 24 has a plurality of height reducing portions 54 that are formed in positions where the spacers 30 are set up individually. Each height reducing portion 54 has a recess 56 that is formed on the same side of the supporting substrate 24 as the first surface 24a, and is formed having a plate thickness smaller than, e.g., equal to half or less of, the plate thickness of the other part of the supporting substrate. Each first spacer 30a is set up on the height reducing portion 54 on the second surface 24b of the supporting substrate 24 and faces the recess 56. Each recess 56 is formed having a shape similar to that of an end face of the spacer 30 on the side of the supporting substrate 24, that is, an abutting surface, and its area is larger than the area of the abutting surface of the spacer 30. According to the present embodiment, each recess 56 extends over a length covering one electron beam aperture 26 that is situated on each side of the spacer 30, with respect to the second direction Y. With respect to the first direction X, each recess 56 extends over a length covering a plurality of, e.g., four, electron beam apertures 26 that are situated on each side of the spacer 30. Thus, each height reducing portion 54 is formed so as to be elastically deformable along a direction substantially perpendicular to the first surface 24a, that is, along the height direction of the spacer 30.

Each height reducing portion 54 has a plurality of grooves that are individually formed on the second surface 24b of the supporting substrate 24 and situated around the spacer 30. These grooves include a pair of first grooves 58a that are situated individually on the opposite sides of the spacer 30 in the first direction X and a pair of second grooves 58b that are situated individually on the opposite sides of the spacer 30 in the second direction Y. Each first groove 58a extends along the second direction Y and opens into two electron beam apertures 26 that are arranged side by side in the second direction. The plurality of second grooves 58b individually extend along the first direction X and open into two electron beam apertures 26 that are arranged side by side in the first direction. The first and second grooves 58a and 58b are provided opposite the recess 56 and formed symmetrically with respect to the spacer 30 in the first direction X and the second direction Y.

Various methods may be used to work the recesses 56 and the first and second grooves 58a and 58b in the supporting substrate 24. In the case where etching is used in the manufacture of the supporting substrate 24, for example, the recesses 56 and the first and second grooves 58a and 58b can be worked easily and simultaneously by half-etching the supporting substrate. Alternatively, the recesses 56 and the first and second grooves 58a and 58b may be formed by machining, such as press working. The surface of the supporting substrate 24, including the respective inner surfaces of the recesses 56 and the first and second grooves 58a and 58b, is covered by the insulating layer 37.

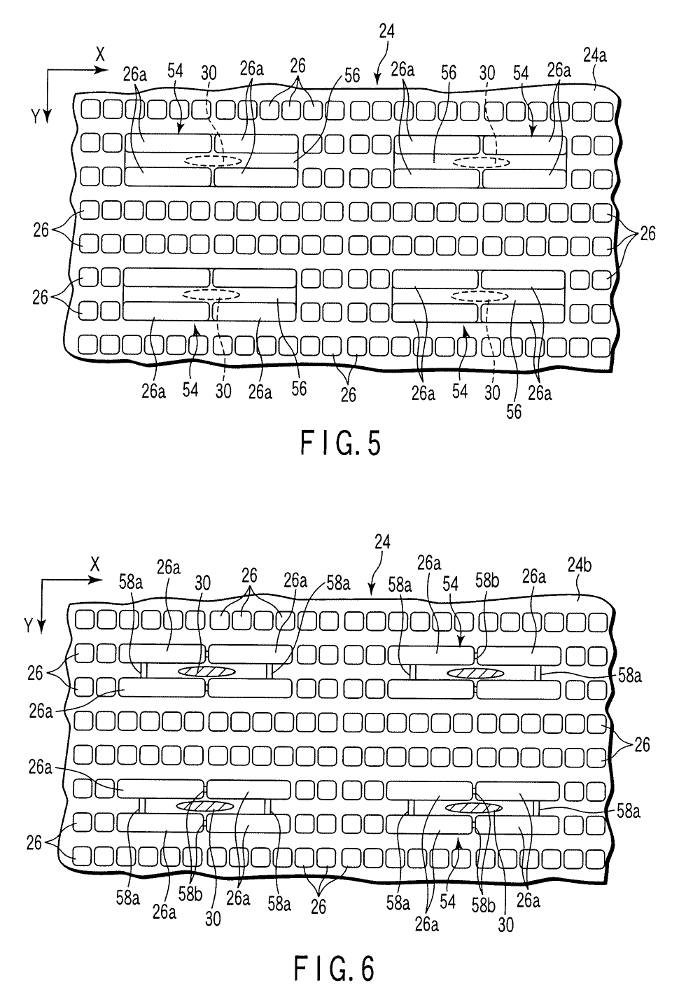

In each height reducing portion 54, as shown in FIGS. 5 to 7, electron beam apertures 26a that are situated on the opposite sides of the spacer 30 along the second direction Y are formed having a length in the first direction X greater than the length of the other electron beam apertures 26. For example, two electron beam apertures 26a that are situated on one side of the spacer 30 are formed as slots. These electron beam apertures 26a are also formed symmetrically with respect to the spacer 30 in the first direction X and the second direction Y.

Since each height reducing portion 54 has the first and second grooves 58a and 58b that are provided around the spacer 30, as described above, it is easily elastically deformable along the height direction of the spacer 30. As the height reducing portion 54 is elastically deformed, it can prevent deformation or distortion of its surroundings. Since the electron beam apertures 26a on the opposite sides of the spacer 30 are formed as slots that are larger than the other electron beam apertures 26, moreover, the height reducing portion 54 can be more easily deformed without twisting or influencing its surroundings.

In the spacer structure 22 constructed in this manner, the supporting substrate 24 is in contact with the first substrate 10, and the respective extended ends of the spacers 30 abut on the inner surface of the second substrate 12, thereby supporting an atmospheric load that acts on these substrates and keeping the space between the substrates at a predetermined value.

The SED comprises a voltage supply portion (not shown) that applies voltage to the supporting substrate 24 and the metal back layer 17 of the first substrate 10. For example, voltages of 8 and 10 kV are applied to the supporting substrate and the metal back layer 17, respectively. In displaying an image on the SED, the electron emitting elements 18 are driven so that electron beams are emitted from some arbitrary electron emitting elements, and an anode voltage is applied to the phosphor screen 16 and the metal back layer 17. The electron beams emitted from the electron emitting elements 18 are accelerated by the anode voltage and passed through the electron beam apertures 26 of the supporting substrate 24, whereupon they collide with the phosphor screen 16. Thus, the phosphor layers of the phosphor screen 16 are excited to luminescence and display the image.

The following is a description of a manufacturing method for the SED constructed in this manner. A manufacturing method for the spacer structure 22 will be described first.

After a metal plate of Fe-50% Ni with a plate thickness of 0.12 mm is first degreased, washed, and dried, resist films are formed individually on its opposite surfaces. Subsequently, the opposite surfaces of the metal plate are exposed, developed, and dried to form resist patterns. Thereafter, the electron beam apertures 26 are formed by etching in predetermined positions on the metal plate. At the same time, the first surface side of the metal plate that faces the first substrate 10 is half-etched in predetermined positions to form the plurality of recesses 56. Further, the second surface side of the metal plate that faces the second substrate 12 is half-etched in predetermined positions to form the plurality of first and second grooves 58a and 58b. Thereafter, glass frit is spread to a thickness of 40 μm on the whole surface of the supporting substrate 24, dried, and then fired, whereupon the insulating layer 37 is formed.

Subsequently, a molding die in the form of a rectangular plate is prepared having substantially the same size as the supporting substrate 24. The molding die is a flat plate formed of a transparent material that transmits ultraviolet rays, e.g., clear silicone based mainly on clear polyethylene terephthalate. The molding die has a flat contact surface in contact with the supporting substrate 24 and a large number of bottomed spacer forming holes for molding the spacers. The spacer forming holes individually open in the contact surface of the molding die and are arranged at predetermined spaces. Thereafter, the spacer forming holes of the molding die are loaded with a spacer forming material. A glass paste that contains at least an ultraviolet-curing binder (organic component) and a glass filler is used as the spacer forming material. The specific gravity and viscosity of the glass paste are selected as required.

Then, the molding die is positioned to bring its contact surface into close contact with the second surface 24b of the supporting substrate so that the spacer forming holes loaded with the spacer forming material are situated between the electron beam apertures. Ultraviolet (UV) rays are applied to the loaded spacer forming material from the outer surface side of the supporting substrate 24 and the molding die by using, for example, an ultraviolet lamp or the like, whereupon the spacer forming material is UV-cured. In this case, the molding die is formed of clear silicone as an ultraviolet-transmitting material. Accordingly, ultraviolet rays are applied to the spacer forming material directly and through the molding die. Thus, the loaded spacer forming material can be securely cured to its inner part.

Thereafter, the molding die is released from the supporting substrate 24 with the cured spacer forming material left on the supporting substrate 24. Then, after the supporting substrate 24 with the spacer forming material thereon is heat-treated in a furnace so that the binder is evaporated from the spacer forming material, the spacer forming material is regularly fired to be vitrified at about 500 to 550° C. for 30 minutes to 1 hour. Thereupon, the spacer structure 22 is obtained having the spacers 30 built in integrally on the second surface 24b of the supporting substrate 24.

In the manufacture of the SED, on the other hand, the first substrate 10, which is provided with the phosphor screen 16 and the metal back layer 17, and the second substrate 12, which is provided with the electron emitting elements 18 and the wires 21 and to which the sidewall 14 is joined, are prepared in advance. Subsequently, after the spacer structure 22 obtained in this manner is positioned on the second substrate 12, four corners of the supporting substrate 24 are welded to metallic posts that are set up on four corner portions of the second substrate, individually. By doing this, the spacer structure 22 is fixed to the second substrate 12. It is necessary only that the supporting substrate 24 be fixed at two spots at the least.

Thereafter, the first substrate 10 and the second substrate 12 to which the spacer structure 22 is fixed are located in a vacuum chamber, the vacuum chamber is evacuated, and the getter film 19 is formed on the metal back layer 17 of the first substrate. Subsequently, the first substrate 10 is joined to the second substrate 12 by means of the sidewall 14, and the spacer structure 22 is interposed between these substrates. Thus, the SED with the spacer structure 22 is manufactured.

According to the SED constructed in this manner, the spacers 30 are provided only on the second substrate 12 side of the supporting substrate 24, so that the length of each spacer can be increased, and the distance between the supporting substrate 24 and the second substrate 12 can be extended. By doing this, the pressure resistance between the supporting substrate and the second substrate is improved, so that generation of electric discharge between these substrates can be suppressed.

The supporting substrate 24 has the height reducing portions 54, and the spacers 30 are provided individually on the height reducing portions. The height reducing portions 54 function as plate springs or coned-disc springs and can absorb dispersion in height, if any, of the spacers 30 by being elastically deformed. If an atmospheric pressure acts in the case where there are some spacers 30 that are taller than the other spacers 30, for example, the height reducing portions 54 of the supporting substrate 24 on which the spacers 30 are set up are elastically deformed on the first substrate 10 side, as shown in FIG. 8, thereby absorbing dispersion of the spacer height. The height reducing portion 54 has the first and second grooves 58a and 58b, and the electron beam apertures 26a on the opposite sides of the spacer 30 are in the form of slots. Therefore, the height reducing portion 54 can be elastically deformed without causing deformation or distortion of its surroundings. Thus, the respective distal end portions of all the spacers 30 can abut on the second substrate 12 without gaps.

Accordingly, an atmospheric load that acts on the first substrate 10 and the second substrate 12 can be stably supported by the spacers 30, so that the atmospheric pressure resistance of the vacuum envelope 15 can be improved. At the same time, damage to the spacers that is attributable to dispersion in height can be prevented.

If the spacers 30 are subject to dispersion in height, moreover, generation of gaps between the distal ends of the spacers and the second substrate 12 can be prevented, so that electric discharge that is attributable to those gaps can be suppressed. Since the supporting substrate 24 is covered by the insulating layer 37, the supporting substrate itself can function as a shield that suppresses electric discharge. Thus, there may be obtained the SED that can suppress generation of electric discharge and has improved atmospheric pressure resistance.

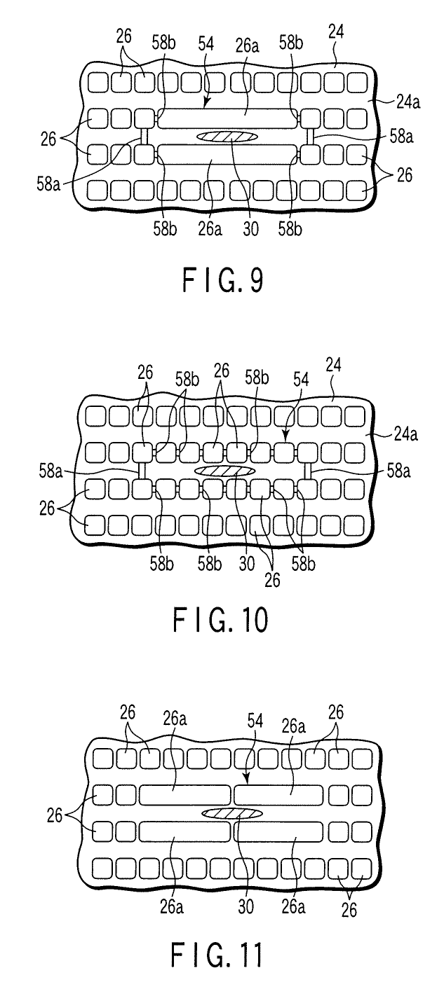

The following is a description of an SED according to a second embodiment of this invention. According to the second embodiment, as shown in FIG. 9, one electron beam aperture 26a situated on each side of a spacer 30, out of electron beam apertures, is formed as a slot in each height reducing portion 54 of a supporting substrate 24. Each first groove 58a extends between electron beam apertures 26 that are situated adjacent to the electron beam apertures 26a. Each second groove 58b extends between the electron beam aperture 26 and an electron beam aperture 26 situated adjacent thereto in the first direction X.

In an SED according to a third embodiment of this invention, as shown in FIG. 10, a supporting substrate 24 has no electron beam aperture 26a in the form of a slot, and all electron beam apertures are formed having a common size. In each height reducing portion 54, second grooves 58b extend between a plurality of electron beam apertures 26 along the first direction X and surround a spacer 30.

In the second and third embodiments, other configurations of the SED are the same as those of the foregoing first embodiment, so that like reference numerals are used to designate like portions, and a detailed description thereof is omitted. The same functions and effects of the first embodiment can be also obtained from the second and third embodiments.

In an SED according to a fourth embodiment of this invention, as shown in FIG. 11, a height reducing portion 54 of a supporting substrate 24 is composed of a combination of a recess 56 and oblong electron beam apertures 26a without first and second grooves. Specifically, in each height reducing portion 54, the recess 56 is formed in a first surface 24a of the supporting substrate 24 and faces a spacer 30. In each height reducing portion 54, electron beam apertures 26a that are situated on the opposite sides of the spacer 30 along the second direction Y are formed having a length in the first direction X greater than the length of other electron beam apertures 26. For example, two electron beam apertures 26a that are situated on one side of the spacer 30 are formed as slots. These electron beam apertures 26a are also formed symmetrically with respect to the spacer 30 in the first direction X and the second direction Y.

In the fourth embodiment, other configurations of the SED are the same as those of the foregoing first embodiment, so that like reference numerals are used to designate like portions, and a detailed description thereof is omitted. The same functions and effects of the first embodiment can be also obtained from the first embodiment.

The present invention is not limited directly to the embodiments described above, and its components may be embodied in modified forms without departing from the spirit of the invention. Further, various inventions may be formed by suitably combining a plurality of components described in connection with the foregoing embodiments. For example, some of the components according to the embodiments may be omitted. Furthermore, components according to different embodiments may be combined as required.

The diameter and height of the spacers and the dimensions, materials, etc., of the other components are not limited to the foregoing embodiments, but may be suitably selected as required. This invention is not limited to image display devices that use surface-conduction electron emitting elements as electron sources, but may be also applied to image display devices that use other electron sources, such as the field-emission type, carbon nanotubes, etc.

What is claimed is:

1. An image display device comprising:
an envelope having a first substrate formed with a phosphor screen and a second substrate which is located opposite the first substrate across a gap and on which a plurality of electron emission sources for electron emission toward the phosphor screen are located;
a supporting substrate located between the first and second substrates and having a first surface opposed to the first substrate, a second surface opposed to the second substrate, and a plurality of electron beam apertures opposed to the electron emission sources; and
a plurality of columnar spacers which are set up between the second surface of the supporting substrate and the second substrate and support an atmospheric pressure acting on the first and second substrates,
the supporting substrate having a plurality of height reducing portions being individually in contact with the spacers and elastically deformable in the height direction of the spacers, each of the height reducing portions having a recess formed in the first surface so as to face the spacer and a plurality of grooves formed on the second surface and situated around the spacer.

2. The image display device according to claim 1, wherein the recess has an area greater than an area of an abutting surface of the spacer which abuts on the supporting substrate.

3. The image display device according to claim 2, wherein the plurality of grooves are formed on the second surface of the supporting substrate so as to face the recess.

4. The image display device according to claim 1, wherein the plurality of electron beam apertures are formed side by side with gaps therebetween in a first direction and a second direction perpendicular to the first direction, the spacers being located between the electron beam apertures arranged in the second direction, and the grooves of each of the height reducing portions include a pair of first grooves which are situated individually on the opposite sides of the spacer in the first direction and communicate individually with the electron beam apertures arranged in the second direction and a plurality of second grooves which are situated on the opposite sides of the spacer in the second direction and communicate individually with the electron beam apertures arranged in the first direction.

5. The image display device according to claim 4, wherein those electron beam apertures which are situated on the opposite sides of the spacer in the second direction are formed having a length in the first direction greater than the length of other electron beam apertures.

6. The image display device according to claim 4, wherein the plurality of grooves of each of the height reducing portions are formed symmetrically with respect to the spacer in the first direction and the second direction.

7. The image display device according to claim 1, wherein each of the recesses is formed by half-etching.

8. An image display device comprising:
an envelope having a first substrate formed with a phosphor screen and a second substrate which is located opposite the first substrate across a gap and on which a plurality of electron emission sources for electron emission toward the phosphor screen are located;
a supporting substrate located between the first and second substrates and having a first surface opposed to the first substrate, a second surface opposed to the second substrate, and a plurality of electron beam apertures opposed to the electron emission sources; and
a plurality of columnar spacers which are set up between the second surface of the supporting substrate and the second substrate and support an atmospheric pressure acting on the first and second substrates,
the supporting substrate having a plurality of height reducing portions being individually in contact with the spacers and elastically deformable in the height direction of the spacers, each of the height reducing portions having a recess formed in the first surface so as to face the spacer, the electron beam apertures on the opposite sides of each spacer in each of the height reducing portions being larger than the other electron beam apertures.

9. The image display device according to claim 8, wherein the plurality of electron beam apertures are formed side by side with gaps therebetween in a first direction and a second direction perpendicular to the first direction, the spacers being located between the electron beam apertures arranged in the second direction, and the electron beam apertures situated on the opposite sides of the spacer in the second direction have a length in the first direction greater than the length of the other electron beam apertures.
